(19) United States
(12) Patent Application Publication
(10) Pub. No.: US 2012/0193486 A1
(43) Pub. Date: Aug. 2, 2012

(54) Swivel Stand

(76) Inventor: Robert Levin, Navarre, FL (US)

(21) Appl. No.: 13/353,624

(22) Filed: Jan. 19, 2012

Related U.S. Application Data
(60) Provisional application No. 61/437,973, filed on Jan. 31, 2011.

(51) Int. Cl. H05K 7/00

(52) U.S. Cl. 248/124.1

(57) ABSTRACT

Flat screen television sets used in a bedroom are commonly placed upon a dresser or mounted on a wall. This takes up room on the dresser and restricts viewing from much of the room and causes strained viewing from other locations in the room.

I found that there are currently no products which solve this problem.

I have invented a swivel television stand that is mounted on a pedestal which has a base which allows the stand to slide under any size bed or to be placed anywhere in the room. The swivel also allows the television to be tilted or raised or lowered with ease. There is a shelf on the stand which holds gaming devices, cable boxes, dvd players, etc.

The swivel stand is designed in such a way that allows viewing from any place in the room without straining and it takes up no extra dresser space.

### BRIEF DESCRIPTION OF THE DRAWINGS

FIG. 1 is an oblique perspective view of a swivel stand according to an embodiment of the present invention in use;

FIG. 2 is a detail rear perspective view of the swivel stand of FIG. 1;

FIG. 3 is a side perspective view of the swivel stand of FIG. 1;

FIG. 4 is a side perspective view of the swivel stand of FIG. 1;

FIG. 5 is a side perspective view of the swivel stand of FIG. 1 taken along the line 5-5;

FIG. 6 is a top plan view of the swivel stand of FIG. 1 taken along the line 6-6; and

FIG. 7 is a detail view of the swivel stand of FIG. 1 indicated by line 7-7.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, embodiments of the present invention generally provide a swivel stand, comprising a horseshoe shaped base for circumventing a post of a bed, a pedestal attached to the base for providing a cable conduit and a support for a shelf, which is attached to the pedestal, a swivel unit attached to the pedestal for supporting a display and providing movement thereof relative to the pedestal, and a plate attached to the swivel unit for providing mounting of the display. Aspects of the present invention provide a swivel stand for a display that provides an electrical conduit for the display, provides tilt, pan, and height adjustability therefor, and provides maneuverability of the swivel stand about obstacles such as a support post.

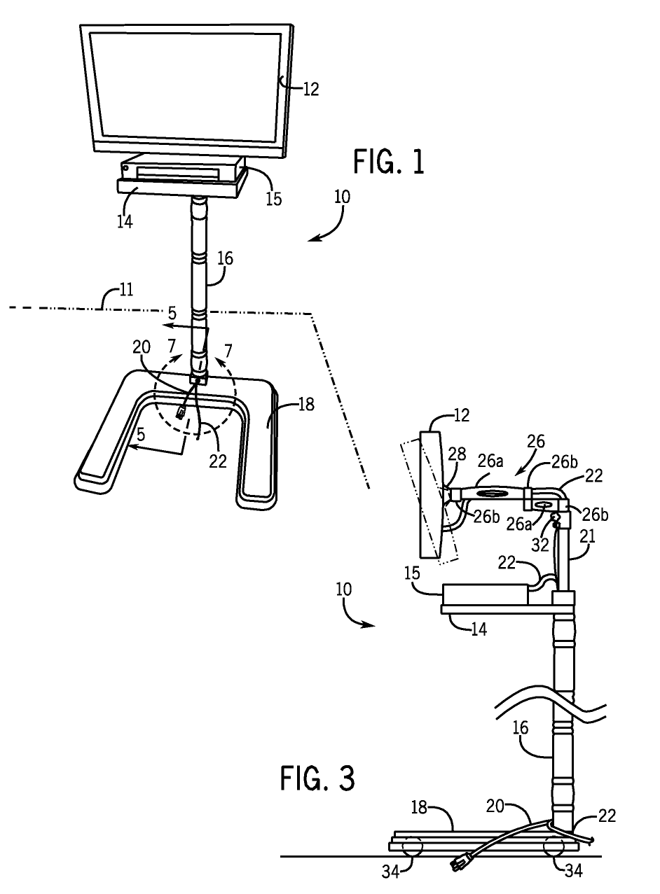

With reference to the Figures, like references refer to like elements in the several drawings. Referring now to FIGS. 1, 3, 4, and 7, an oblique perspective view of a swivel stand 10, side perspective views of swivel stand 10, and a detail view of swivel stand 10 indicated by line 7-7 are shown respectively. Swivel stand 10 may have a base 18 having a plurality of casters 34 on a bottom side thereof. Swivel stand 10 may be attached to a pedestal 16, which may extend vertically therefrom to a shelf 14. Shelf 14 may extend horizontally from pedestal 16 and may provide a surface for a device including, for example, a cable box 15a, media player, game console, or other video playback device. Pedestal 16 may be configured to contain a plurality of wires or cables including, for example, a power cord 20, a coaxial cable 22, a video cable, and an audio cable. Pedestal 16 may act as a conduit for the plurality of wires or cables, conveying them from one end of pedestal 16 to another end thereof. In an embodiment of the present invention, the plurality of wires or cables transmitted by pedestal 16 may be assembled inside a sheath 24, which may be a wire loom, a cable sheath, or flexible conduit.

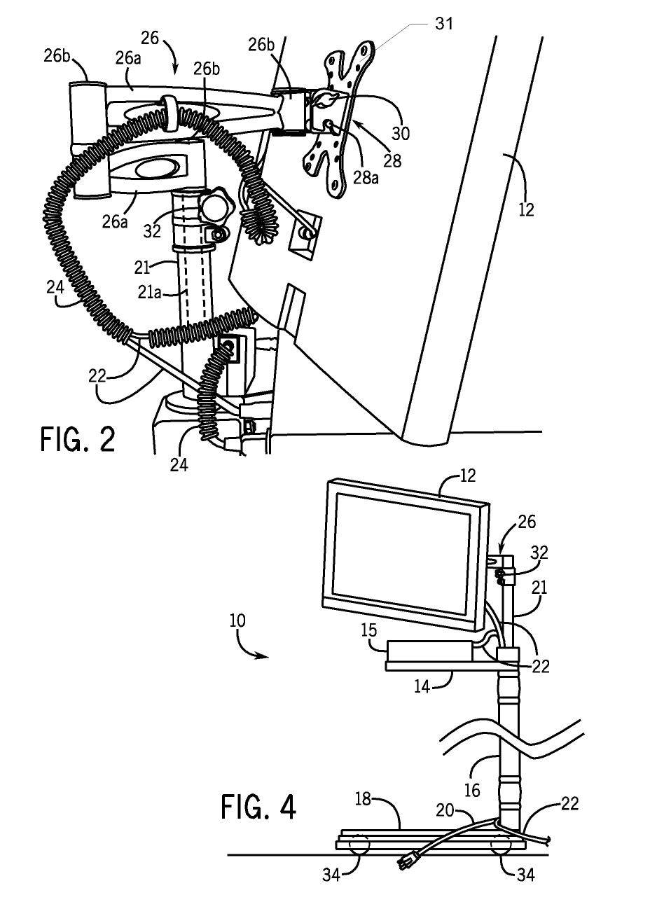

Referring now to FIG. 2, a detail rear perspective view of swivel stand 10 is shown. Pedestal 16 may have a post casing 21 extending from a top side thereof. Post casing 21 may have a post 21a (illustrated by dashed lines) located therein, which may slidingly engage and may be concentric with post casing 21. Post 21 a may telescope or extend with respect to post casing 21, and may be affixed or secured in place with a lock knob 32. Post 21 a may have a horizontal swivel unit 26 attached thereto. Horizontal swivel unit 26 may have elements configured to move in a horizontal plane and may be attached to a tilt swivel unit 28, which may have elements configured to move in a vertical plane and may be affixed to a display 12. Display 12 may include, for example, a television, a monitor, a screen, or a mirror.

Horizontal swivel unit 26 may include first and second horizontal swivel arms 26a and first, second, and third horizontal swivel joints 26b. Horizontal swivel unit 26 may be attached to post 21a by first horizontal swivel joint 26b, which may provide movement or rotation thereabout of a first horizontal swivel arm 26a. First horizontal swivel arm 26a may be attached to second horizontal swivel arm 26a with second horizontal swivel joint 26b, which may provide movement or rotation therebetween. Second horizontal swivel arm 26a may be attached to third horizontal swivel joint 26b, which may provide movement or rotation thereabout with a tilt swivel unit 28. Tilt swivel unit 28 may provide vertical tilt for a plate 31, which may rotate about a vertical tilt joint 28a, and may be locked in place or affixed by a tilt lock 30. Plate 31 may be a mounting plate or other device that may be fastened to display 12, providing support thereto.

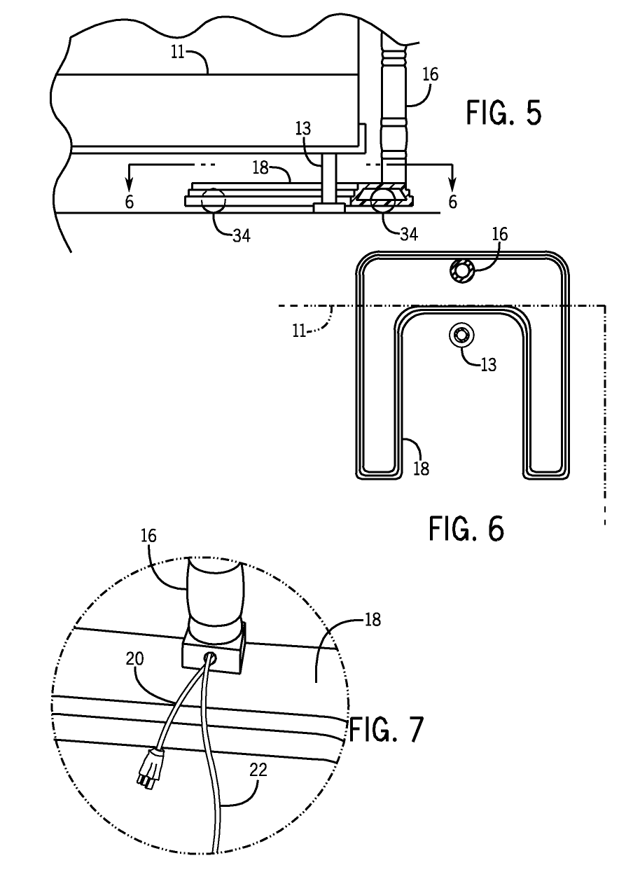

Referring now to FIGS. 5 and 6, a side perspective view of swivel stand 10 and a top plan view of swivel stand 10 of taken along line 6-6 are shown respectively. Base 18 may be configured to have portions capable of extending beneath a bed 11 and circumvent a support post 13. In an exemplary embodiment, base 18 may be horseshoe shaped, or “U” shaped, and may have first and second side elements extending from opposites sides of a center element. In other embodiments, base 18 may be “V” shaped, “Y” shaped, “X” shaped, “L” shaped, circular, and may have straight or arcuate segments.

In another embodiment of the present invention, servo motors, linear actuators, springs, dampers, and pneumatic or hydraulic pistons may be installed on at least one of the post casing 21, post 21a, the plurality of horizontal swivel arms 26a or joints 26b, vertical tilt joint 28a, or plate 31, and may provide remote or automatic control of swivel stand 10.

It should be understood, of course, that the foregoing relates to exemplary embodiments of the invention and that modifications may be made without departing from the spirit and scope of the invention as set forth in the following claims.

What is claimed is:

1. A swivel stand, comprising:
a base, the base configured to circumvent a post;
a pedestal attached to the base and extending vertically from the base, the pedestal configured to act as a cable conduit;
a shelf attached to the pedestal, the shelf extending horizontally from the pedestal;
a horizontal swivel unit attached to the pedestal, the horizontal swivel unit configured to move in a horizontal plane;
a tilt swivel unit attached to the horizontal swivel unit, the tilt swivel unit configured to move in a vertical plane; and
a plate attached to the tilt swivel unit, the plate configured to fasten to a display.
